(19) United States
(12) Patent Application Publication
(10) Pub. No.: US 2026/0210800 A1
(43) Pub. Date: Jul. 23, 2026

(54) SILICON PHOTONIC WAFER TESTING SYSTEM AND TESTING METHOD THEREOF

(71) Applicant: HERMES TESTING SOLUTIONS INC., Hsinchu City (TW)

(72) Inventor: Wen-Yuan Hsu, Hsinchu City (TW)

(73) Assignee: HERMES TESTING SOLUTIONS INC., Hsinchu City (TW)

(21) Appl. No.: 19/312,333

(22) Filed: Aug. 28, 2025

Related U.S. Application Data
(60) Provisional application No. 63/747,347, filed on Jan. 21, 2025.

(30) Foreign Application Priority Data
Apr. 8, 2025 (TW) 114113130

(51) Int. Cl. G01M 11/02; G01M 11/08

(52) U.S. Cl. CPC G01M 11/0214; G01M 11/085

(57) ABSTRACT

A silicon photonics wafer testing system includes a wafer prober, an optical coupling actuator, an optical measurement instrument, and an integrated control module. The wafer prober includes an upward-facing camera, a downward-facing camera, and a probe card. A silicon photonics wafer is adapted to be carried on a stage of the wafer prober. The probe card is disposed above the stage. At least one optical fiber array is adapted to be carried on a fiber holder of the optical coupling actuator. The optical fiber array is located on an optical measurement path of the optical measurement instrument. The integrated control module is electrically connected to the wafer prober, the optical coupling actuator, and the optical measurement instrument. A silicon photonics wafer testing method is also provided.

### CROSS-REFERENCE TO RELATED APPLICATION

This application claims the priority benefit of U.S. Provisional Application No. 63/747,347, filed on Jan. 21, 2025 and Taiwan Application No. 114113130, filed on Apr. 8, 2025. The entirety of each of the above-mentioned patent applications is hereby incorporated by reference herein and made a part of this specification.

### BACKGROUND

### Technical Field

The disclosure relates to a silicon photonics wafer testing system and a testing method thereof.

### Description of Related Art

In the existing silicon photonics wafer testing, two separate steps are needed to separately position (align) the optical fiber array and the grating, in no particular order. Step one is to manually move the fiber optic or optical fiber array (FA) to an approximate position above the grating coupler (GC) or edge coupler (EC). Afterward, Step two uses a downward-facing camera or side-view camera plus a 45-degree prism optical lens to find the side image line of the fiber optic or optical fiber array as a reference. Then, the coordinate position of the reference is used as the starting point for optical coupling.

However, the errors generated by the above Steps one and two are large, requiring a large search range to find the initial light and coupling peak, which consumes a significant amount of time. In Step one, the manual movement plus visual manual alignment error is approximately +/−500 um, while in Step two, the total error caused by structural chipping or cracking in the body structure of the fiber optic or optical fiber array due to manufacturing or caused by visual focusing is approximately +/−105 um.

The above errors lead to the initial positioning operation requiring a search from a larger range to compensate for the positioning problem caused by insufficient precision. Further, this results in the overall optical coupling process being divided into two stages. The first stage is the installation setup stage, which requires setting the maximum search range and then recording this position as a baseline for use in the production stage (this stage takes approximately 60 minutes to 200 minutes). Moreover, the second stage is the production stage, which uses the position from the first stage plus the necessary search range to find the initial light and the optical coupling energy peak (this stage takes approximately 15 seconds to 20 seconds). The above not only increases the complexity and time required for positioning or coupling, but also requires both stages to be reset whenever a new silicon photonics wafer product or an optical fiber array with a different number of channels is changed, obviously making the process time-consuming and inconvenient.

### SUMMARY

The disclosure provides silicon photonics wafer testing system and a silicon photonics wafer testing method through which testing steps are effectively simplified and testing time is saved.

The disclosure provides a silicon photonics wafer testing system including a wafer prober, an optical coupling actuator, an optical measurement instrument, and an integrated control module. The wafer prober includes an upward-facing camera, a downward-facing camera, and a probe card. A silicon photonics wafer is adapted to be carried on a stage of the wafer prober. The probe card is disposed above the stage. At least one optical fiber array is adapted to be carried on a fiber holder of the optical coupling actuator. The optical fiber array is located on an optical measurement path of the optical measurement instrument. The integrated control module is electrically connected to the wafer prober, the optical coupling actuator, and the optical measurement instrument. The integrated control module drives the upward-facing camera to be aligned with the probe card and the at least one optical fiber array, drives the downward-facing camera to be aligned with the silicon photonics wafer and a bonding pad thereon, and combines positional information of a coupler of the silicon photonics wafer, so as to obtain a relative positional relationship among the probe card, the optical fiber array, and the bonding pad and the coupler of the silicon photonics wafer on the wafer prober.

The disclosure further provides a silicon photonics wafer testing method adapted to the silicon photonics wafer testing system according to the above. The testing method includes the following steps. The silicon photonics wafer is transported and loaded onto the stage of the wafer prober. An alignment step including alignment 1, alignment 2, and alignment 3 is performed, where alignment 1 is to align the upward-facing camera with a probe of the probe card, alignment 2 is to align the upward-facing camera with the optical fiber array by, and alignment 3 is to align the downward-facing camera with the silicon photonics wafer and the bonding pad thereon. After the alignment step is completed, the integrated control module combines the positional information of the coupler of the silicon photonics wafer and drives the stage to move the silicon photonics wafer toward the probe card until the probe contacts the bonding pad of the silicon photonics wafer with preset probe pressing. The integrated control module then drives the optical coupling actuator to move the optical fiber array to a position corresponding to the coupler and then performs optical coupling until a preset distance is reached.

Accordingly, through the architecture of the wafer prober as an object alignment aid, the alignment of the optical fiber array with the silicon photonics wafer is obtained. Further, a definite probe pressing contact between the probe card and the silicon photonics wafer is completed, so the two is mutually positioned. In this way, the optical fiber array and silicon photonics wafer are able to perform related optical testing or opto-electronic testing directly after executing the subsequent optical coupling operations. Through the above testing system and testing method, operational precision is effectively improved (alignment errors are reduced), so that the preliminary operations and optical coupling operations of the silicon photonics wafer are simplified, and time also is saved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of a silicon photonics wafer testing system according to an embodiment of the disclosure.

FIG. 2, FIG. 3A, and FIG. 3B are schematic views of silicon photonics wafer testing systems according to different embodiments of the disclosure.

FIG. 4 is a schematic view of a probe card according to the disclosure.

FIG. 5 is a flow chart of a silicon photonics wafer testing method according to an embodiment of the disclosure.

FIG. 6A to FIG. 6G are schematic views of processes of the silicon photonics wafer testing method.

### DESCRIPTION OF THE EMBODIMENTS

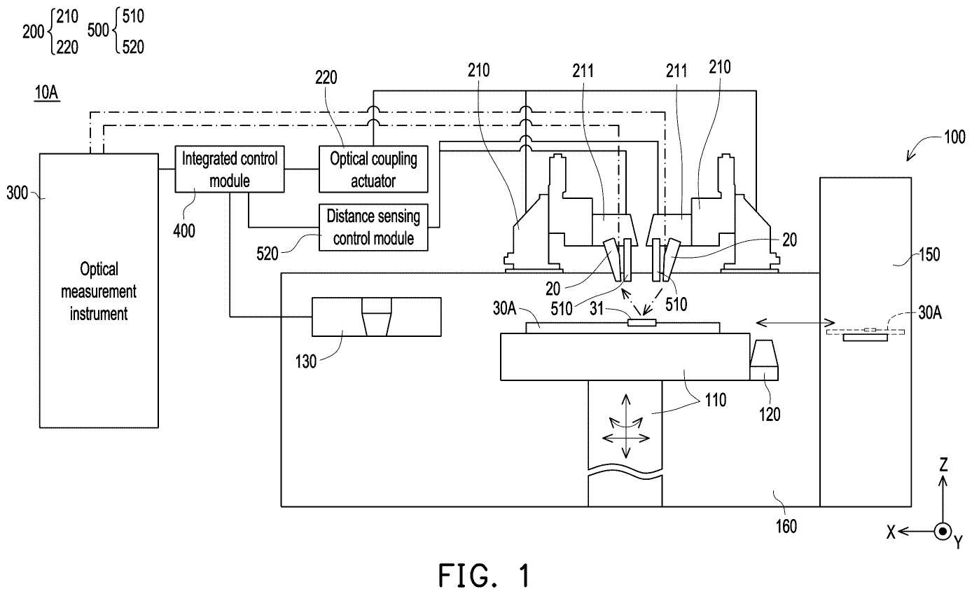

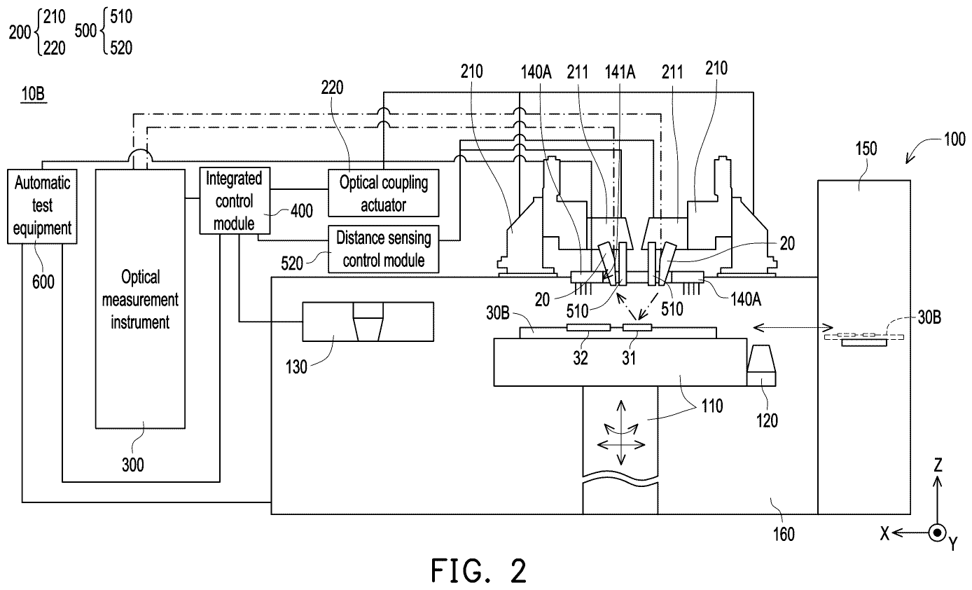

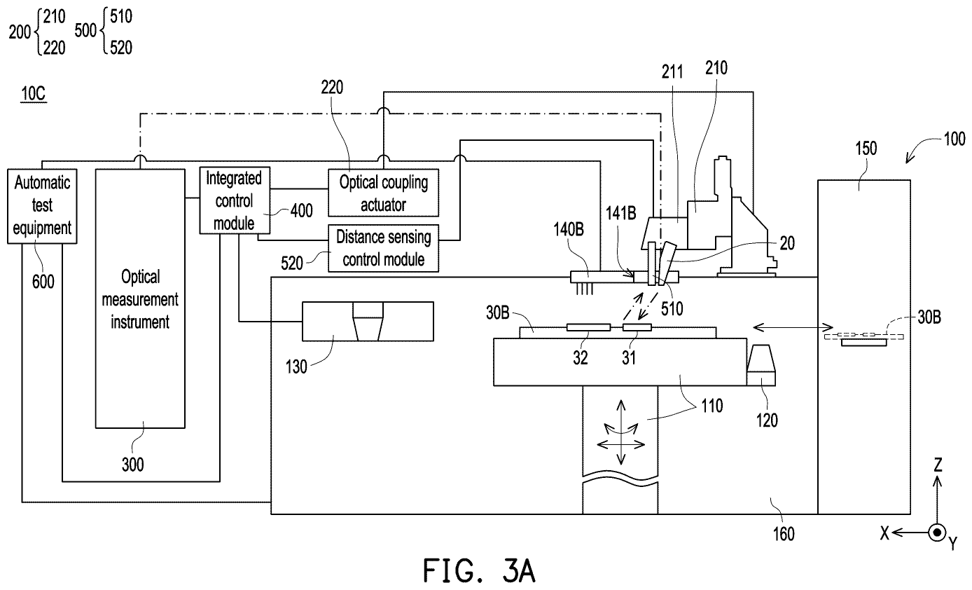

FIG. 1 is a schematic view of a silicon photonics wafer testing system according to an embodiment of the disclosure. FIG. 2, FIG. 3A, and FIG. 3B are schematic views of silicon photonics wafer testing systems according to different embodiments of the disclosure. Herein, FIG. 1 shows a schematic of a silicon photonics wafer testing system 10A performing optic-to-optic testing on a silicon photonics wafer 30A and an optical fiber array 20, while FIG. 2, FIG. 3A, and FIG. 3B show silicon photonics wafer testing systems 10B and 10C performing optic-to-electric (as in FIG. 3A or FIG. 3B) or optic-to-electric-to-optic (as in FIG. 2) testing on a silicon photonics wafer 30B, where some components are not repeated due to different testing forms. However, overall, the silicon photonics wafer testing systems 10A, 10B, and 10C may include the aforementioned non-repeated components to facilitate maintaining their structural integrity and applicability.

Referring to FIG. 1 to FIG. 3A together, in this embodiment, each of the silicon photonics wafer testing systems 10A, 10B, and 10C includes a wafer prober 100, an optical coupling actuator 200, an optical measurement instrument 300, and an integrated control module 400. The integrated control module 400 is, for example, a multifunctional computer workstation including a processor, memory, and central control software and electrically connected to the wafer prober 100, the optical coupling actuator 200, and the optical measurement instrument 300, so as to facilitate execution of integrated operations such as electrical driving, message determination, and message communication.

The wafer prober 100 includes an upward-facing camera 120, a downward-facing camera 130, and probe cards 140A and 140B. The silicon photonics wafers 30A and 30B are adapted to be carried on a stage 110 of the wafer prober 100. The probe cards 140A and 140B are disposed above the stage 110. Further, the wafer prober 100 also includes a probe testing platform 160 and a wafer transporter 150. The upward-facing camera 120, the downward-facing camera 130, the probe card 140A, and the stage 110 are disposed inside the probe testing platform 160, where the probe card 140A is detachably installed on a top portion of the probe testing platform 160. The wafer transporter 150 is disposed beside the probe testing platform 160 to facilitate transporting the silicon photonics wafers 30A and 30B to be loaded onto the stage 110 through a loading arm or retrieving the silicon photonics wafers 30A and 30B from the stage 110. A coupling mechanism 210 (for example, including a six-axis freedom arm mechanism) of the optical coupling actuator 200 is disposed on the probe testing platform 160, and the coupling mechanism 210 is controlled by a coupling control module 220 and is electrically connected to the integrated control module 400 accordingly At least one optical fiber array 20 is clamped in a fiber holder 211 of the coupling mechanism 210 and is positioned on an optical measurement path generated by the optical measurement instrument 300, so as to facilitate execution of coupling steps of the optical fiber array 20 and the silicon photonics wafers 30A and 30B. In this embodiment, the optical measurement instrument 300 includes a tunable laser source, a polarization scrambler, an optical switch, and an insertion loss/return loss meter or power meter (IL/RL meter or power meter), and related optical components for coupling and optical testing with the optical fiber array 20 and the silicon photonics wafers 30A and 30B.

Further, each of the silicon photonics wafer testing systems 10A, 10B, and 10C also includes a distance sensing device 500 including a distance sensor 510 and a distance sensing control module 520. The distance sensor 510 is disposed on the fiber holder 211 and is adjacent to the optical fiber array 20. The distance sensor 510 is controlled by the distance sensing control module 520 and is electrically connected to the integrated control module 400 accordingly, for measuring a relative distance between the optical fiber array 20 and the silicon photonics wafers 30A and 30B.

Different from the silicon photonics wafer testing system 10A shown in FIG. 1 which is suitable for optical testing, each of the silicon photonics wafer testing systems 10B and 10C that needs to perform opto-electronic testing also includes an automatic test equipment (ATE) 600, integrated with the wafer prober 100 and electrically connected to the integrated control module 400 and the probe cards 140A and 140B. In this way, the integrated control module 400 is allowed to drive the automatic test equipment 600 to test the electrical characteristics or opto-electronic characteristics of the silicon photonics wafer 30B.

In brief, in the optical testing in FIG. 1, two sets of single-mode optical fibers or optical fiber arrays 20 are provided, where the optical fiber array 20 on the right side of FIG. 1 is located on a light emitting path of the optical measurement instrument 300, and the optical fiber array 20 on the left side is located on a light receiving path of the optical measurement instrument 300. The light from the optical fiber array 20 on the right side is directed toward a coupler 31 (e.g., a grating coupler) of the silicon photonics wafer 30A and then reflected toward the optical fiber array 20 on the left side. Through this optical testing process, it can be determined that whether the optical characteristics of the optical fiber array 20 and the silicon photonics wafer 30A meet the needs.

Further, the opto-electronic testing in FIG. 2 is based on FIG. 1, and influences of electronic components or circuits of the silicon photonics wafer 30B are further added on its optical characteristics. Therefore, on the basis of the aforementioned optics path, the probe card 140A further performs probe testing on a bonding pad 32 of the silicon photonics wafer 30B, so as to perform the optical testing as mentioned above by the optical measurement instrument 300.

In addition, the opto-electronic testing in FIG. 3A is a test performed on the silicon photonics wafer 30B using only a single optical fiber array 20 in together with the probe card 140B. Since the optical fiber array 20 includes multiple optical fibers, in this test, these optical fibers are distinguished according to the light emitting path and light receiving path. That is, some optical fibers are located in the light emitting path, while other optical fibers are located on the light receiving path, so that the optical characteristics of different optical fibers within the optical fiber array 20 are known. Moreover, the interactive effects between the electrical characteristics and the optical characteristics of the silicon photonics wafer 30B as shown in FIG. 2 can also be known. Further, FIG. 3A may also serve to show the impact of the optical characteristics and electrical characteristics on additional equipment when the optical fiber array 20 and the silicon photonics wafer 30B need to be externally connected to the additional equipment.

Different from the couplers 31 on the silicon photonics wafers 30A and 30B in FIG. 1 to FIG. 3A which are grating couplers, the coupler 31A provided in the embodiment of FIG. 3B is an edge coupler, where the difference lies in the different optical fiber transmission modes between the coupler 31A and the optical fiber array 20.

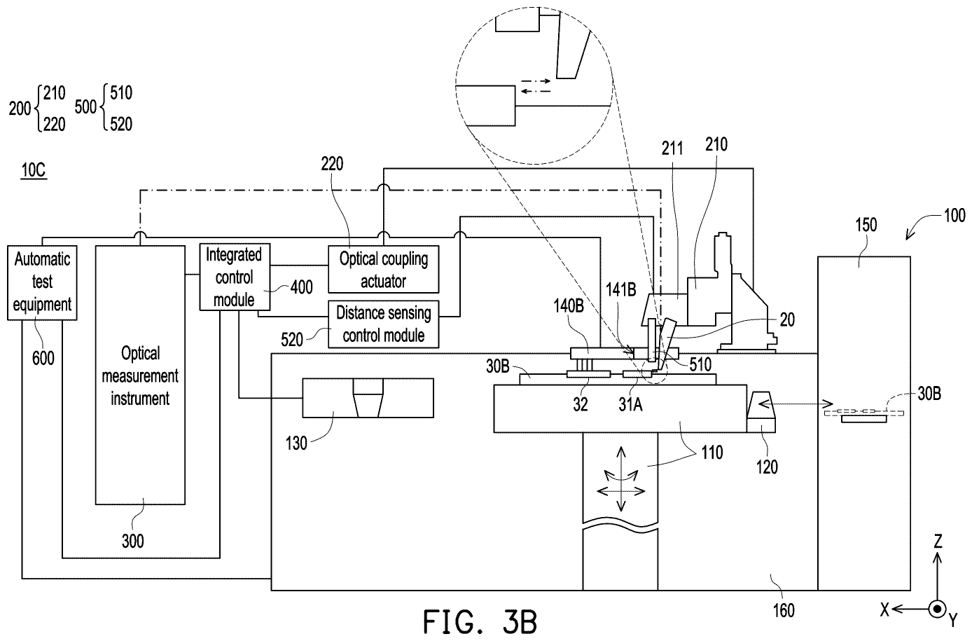

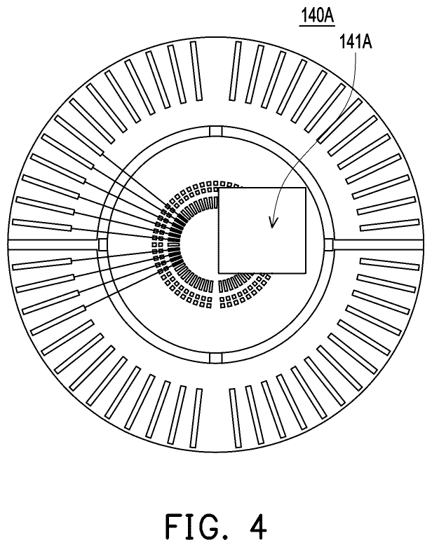

FIG. 4 is a schematic view of a probe card according to an embodiment of the disclosure. Referring to FIG. 4, it is equivalent to a top view of the probe card 140A shown in the aforementioned FIG. 2, FIG. 3A, and FIG. 3B. In this embodiment, the probe card 140A has a window 141A to enable the optical coupling mechanism 210 of the optical coupling actuator 200 to drive the optical fiber array 20 from top to bottom to pass through the window 141A and move toward the silicon photonics wafer 30B in the probe testing platform 160.

Before the aforementioned optical testing or opto-electronic testing is to be performed, in addition to performing optical coupling on the optical fiber array 20 and the silicon photonics wafers 30A and 30B, it is also necessary to complete the alignment of related objects before the optical coupling, so as to effectively simplify the process and save time for the optical coupling (and subsequent testing). Accordingly, in this embodiment, the integrated control module 400 executes relevant alignment steps to obtain relative positional relationships among the probe cards 140A and 140B, the optical fiber array 20, and the silicon photonics wafers 30A and 30B on the wafer prober 100, and then proceeds with the optical coupling and optical testing or opto-electronic testing only after the alignment is completed. Details are provided in the following paragraphs.

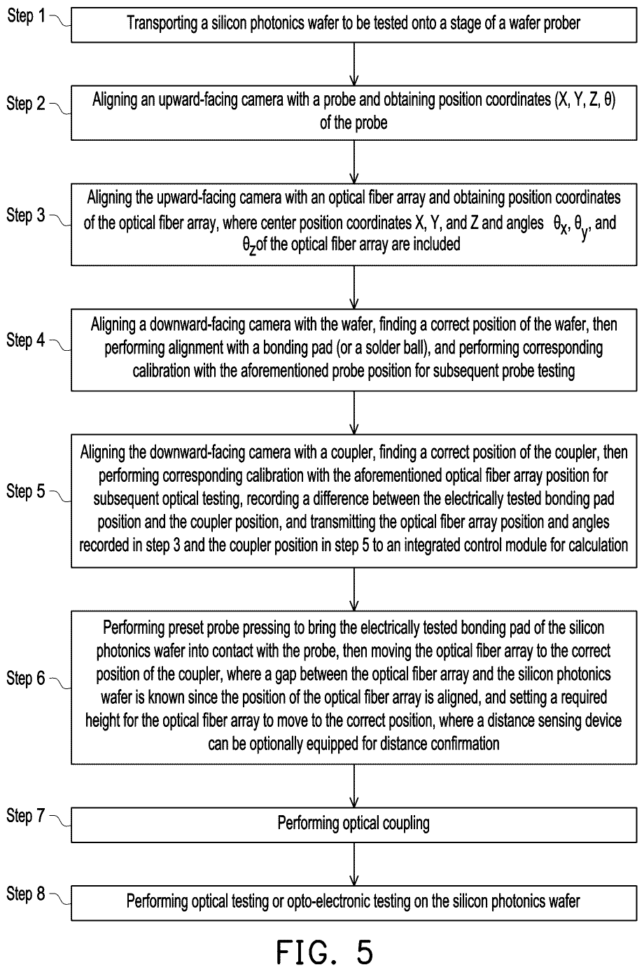

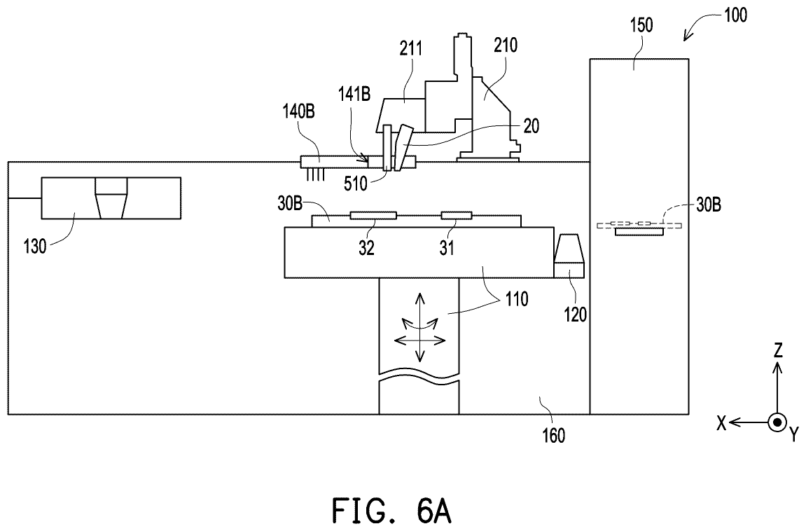

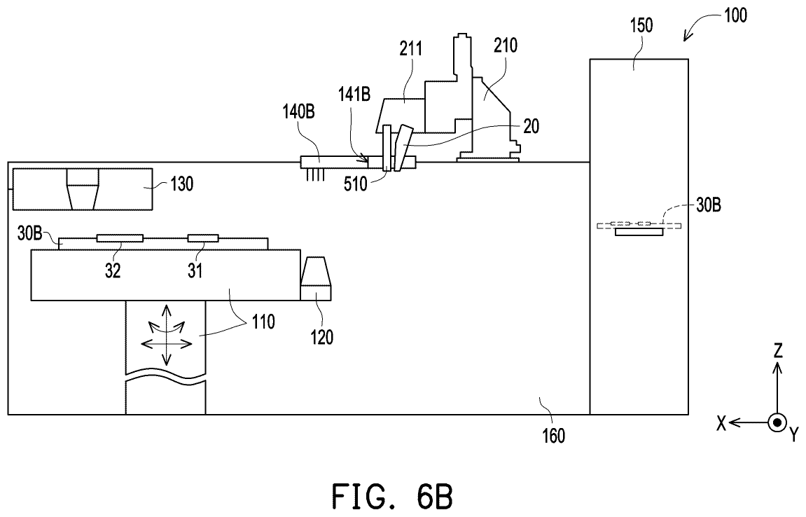

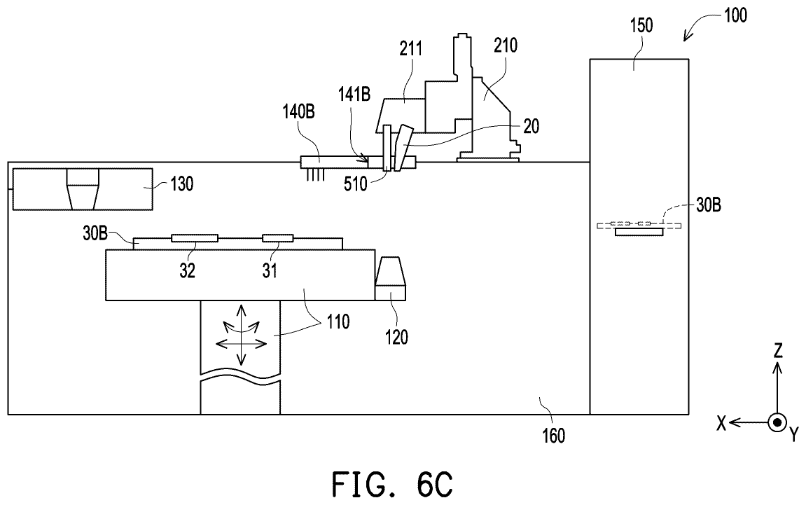

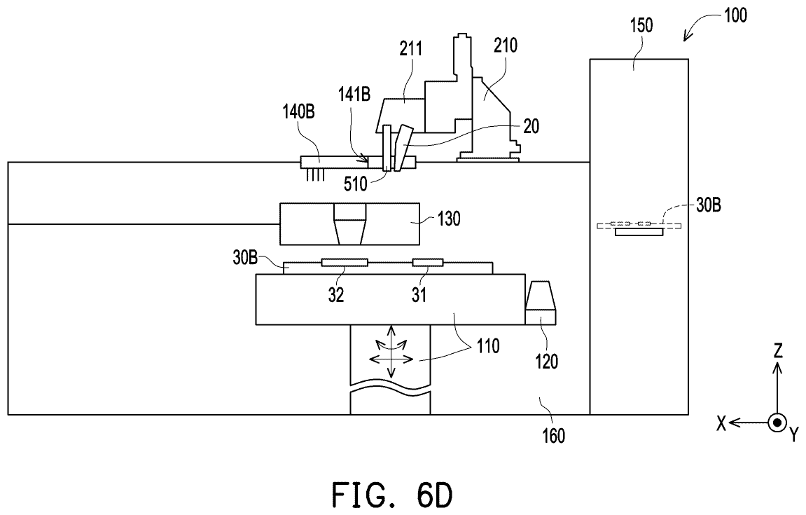

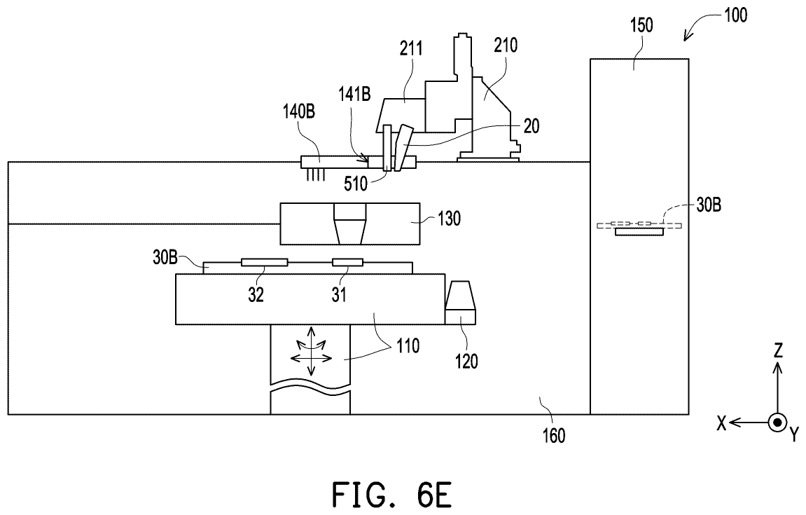

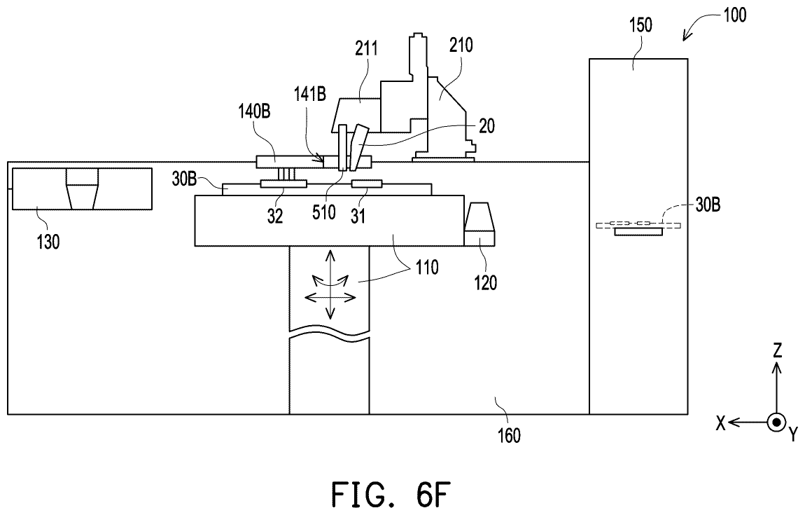

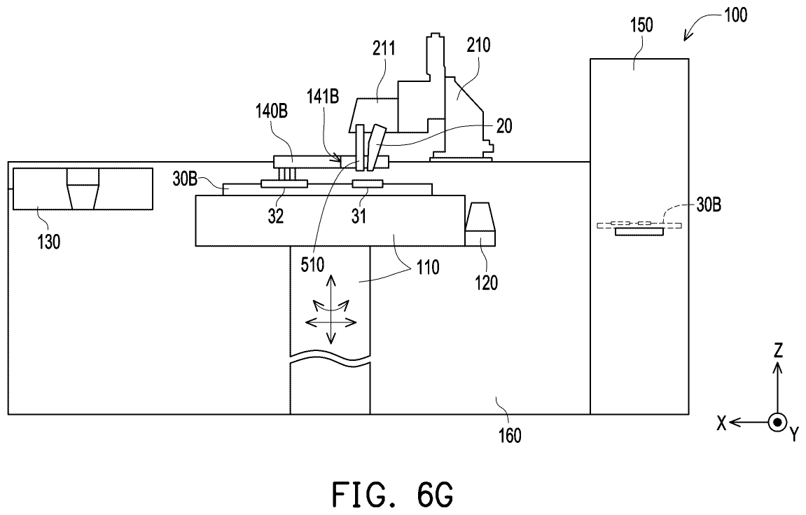

FIG. 5 is a flow chart of a silicon photonics wafer testing method according to an embodiment of the disclosure. FIG. 6A to FIG. 6G are schematic views of processes of the silicon photonics wafer testing method. Referring to the steps in FIG. 5 and sequentially comparing the steps with the corresponding views in FIG. 6A to FIG. 6G, the silicon photonics wafer testing method provided by the disclosure is based on the premise of using the wafer prober 100 as a basic architecture, allowing the silicon photonics wafer 30B and the optical fiber array 20 to complete optical coupling and perform subsequent related tests. In other words, after the silicon photonics wafer 30B is loaded onto the stage 110, the alignment steps are executed, and the alignment steps include alignments for different objects (alignment 1 alignment 2, alignment 3, and alignment 4). After the alignment steps are completed, the optical coupling and subsequent optical testing or opto-electronic testing are performed, as described in details in the following paragraphs.

First, in step 1, as shown in FIG. 5 and FIG. 6A, the integrated control module 400 drives the wafer transporter 150 to transport and load the silicon photonics wafer 30B to be tested onto the stage 110 of the wafer prober 100.

Next, in step 2, as shown in FIG. 6B, the integrated control module 400 drives the upward-facing camera 120 to be aligned with a probe of the probe card 140A (i.e., the aforementioned alignment 1), so as to obtain position coordinates (X, Y, Z, θ) of the probe in the wafer prober 100. In this embodiment, the stage 110 is a movable stage, such as a four-axis rotary table (X, Y, Z, θ), and the upward-facing camera 120 is assembled on a side of the stage 110 to move with the stage 110.

Next, in step 3, as shown in FIG. 6C, the integrated control module 400 drives the upward-facing camera 120 to be aligned with the optical fiber array 20 (i.e., the aforementioned alignment 2), so as to obtain position coordinates of the optical fiber array 20 in the wafer prober 100. Center position coordinates (X, Y, Z) and angles (θₓ, θ_{y}, θ_{z}) of the optical fiber array 20 are included.

Next, the aforementioned alignment 3 is performed, and step 4 and step 5 are included. In step 4, as shown in FIG. 6D, the integrated control module 400 drives the downward-facing camera 130 to be aligned with the silicon photonics wafer 30B, including finding a correct position of the silicon photonics wafer 30B (for example, finding a mark on the silicon photonics wafer 30B). Next, alignment is performed on the bonding pad 32 (or a solder ball) on the silicon photonics wafer 30B. The information obtained after completing the alignment may be used by the integrated control module 400 to perform corresponding calibration with the probe position information obtained in step 2 (the corresponding relationship between the probe and the bonding pad 32 is known), for subsequent probe testing (electrical testing).

Next, in step 5, as shown in FIG. 6E, the alignment steps of this embodiment also include position 4, where the integrated control module 400 drives the downward-facing camera 130 to be aligned with the coupler 31 to obtain position coordinates of the coupler 31 in the wafer prober 100. Further, the information acquired after completing the alignment may be used by the integrated control module 400 for corresponding calibration with the alignment information of the optical fiber array 20 from step 3 to facilitate subsequent optical testing. Further, for the silicon photonics wafer 30B, step 5 may also correspond with step 4 to acquire a differential state between the position of the bonding pad 32 and the position of the coupler 31, to facilitate execution of integrated calculation by the integrated control module 400 together with the position coordinates and angles of the optical fiber array 20 acquired in step 3.

It should be noted that the driving methods of the abovementioned step 4 and step 5 are not limited herein. According to the aforementioned stage 110 being a movable stage, in other embodiments that are not shown, the downward-facing camera 130 may be disposed at a fixed position on the probe testing platform 160, and only the stage 110 is driven toward the downward-facing camera 130 to perform the alignment of the aforementioned step 4 and step 5, or vice versa.

Next, in step 6, as shown in FIG. 6F, the aforementioned alignment 4 is performed, where the integrated control module 400 drives the stage 110 to move the silicon photonics wafer 30B toward the probe card 140B until the probe contacts the bonding pad 32 of the silicon photonics wafer 30B with preset probe pressing, so as to accordingly position the probe card 140A (the probe) and the silicon photonics wafer 30B. As the position of the aforementioned optical fiber array 20 is known in step 3 and the position of the coupler 31 is acquired in step 5, the relative positional relationship can be calculated through integration of these two. Subsequently, as shown in FIG. 6G, when the optical fiber array 20 is moved to the correct position, as shown in step 7, the optical coupling operation between the optical fiber array 20 and the silicon photonics wafer 30B may be performed, where the aforementioned correct position is to maintain a preset distance (e.g., 10 μm) between the optical fiber array 20 and the coupler 31 of the silicon photonics wafer 30B to facilitate optical coupling.

As mentioned above, in each of the silicon photonics wafer testing systems 10A, 10B, and 10C, the distance sensing device 500 is also included. Therefore, in step 6, the relative distance between the optical fiber array 20 and the silicon photonics wafer 30B may also be detected by the distance sensing device 500 as well, and the relative distance serves as a verification of alignment 3, so as to obtain the relative distance (relative height, which is the aforementioned preset distance) between the probe card 140A and the silicon photonics wafer 30B through probe testing.

On the wafer prober 100, the probe card 140A is disposed at a predetermined position on the probe testing platform 160 (as shown in FIG. 2, FIG. 3A, and FIG. 3B). Therefore, the relative positional relationship between the stage 110 and the probe cards 140A and 140B can be considered determined within a specific range to a certain degree, so that the search time required for conventional manual alignment is effectively decreased.

At this point, with the optical coupling completed between the optical fiber array 20 and the silicon photonics wafer 30B, the subsequent step 8 may be performed to execute optical testing or opto-electronic testing. These tests are disclosed in the aforementioned FIG. 1 to FIG. 3A (or FIG. 3B), so description is not repeated herein.

It should also be mentioned that since the aforementioned alignment 1 to alignment 4 are alignment processes for different objects, their execution order need not be restricted.

It should also be mentioned that in another embodiment that is not shown, the aforementioned alignment 4 in the steps may be implemented by another means. That is, built-in information in the silicon photonics wafer substantially includes the position of the coupler thereon. Therefore, when the silicon photonics wafer is loaded onto the stage, the above information may be immediately provided to the integrated control module.

In summary, in the abovementioned embodiments of the disclosure, the silicon photonics wafer testing system and the testing method thereof are implemented through the architecture of the wafer prober, and the alignment of relevant objects is completed through the upward-facing camera, the downward-facing camera, and the probe card. After the upward-facing camera is aligned with the probe and optical fiber array and the downward-facing camera is aligned with the silicon photonics wafer and the bonding pad and the coupler thereon, the probe is further brought into contact with the bonding pad on the silicon photonics wafer. In this way, the corresponding positional relationship among these objects on the wafer prober are obtained by the optical fiber array and the coupler of the silicon photonics wafer based on the above. Subsequently, optical coupling and optical testing or opto-electronic testing may be smoothly performed according to the corresponding positional relationship.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A silicon photonics wafer testing system, comprising:
a wafer prober comprising an upward-facing camera, a downward-facing camera, and a probe card, wherein a silicon photonics wafer is adapted to be carried on a stage of the wafer prober, and the probe card is disposed above the stage;
an optical coupling actuator disposed on the wafer prober, wherein at least one optical fiber array is adapted to be carried on a fiber holder of the optical coupling actuator;
an optical measurement instrument, wherein the at least one optical fiber array is located on an optical measurement path of the optical measurement instrument; and
an integrated control module electrically connected to the wafer prober, the optical coupling actuator, and the optical measurement instrument, wherein the integrated control module drives the upward-facing camera to be aligned with the probe card and the at least one optical fiber array, drives the downward-facing camera to be aligned with a bonding pad of the silicon photonics wafer, and combines positional information of a coupler of the silicon photonics wafer to obtain a relative positional relationship among the probe card, the at least one optical fiber array, and the bonding pad and the coupler of the silicon photonics wafer on the wafer prober.

2. The silicon photonics wafer testing system according to claim 1, wherein the probe card has a window for the optical coupling actuator to drive the at least one optical fiber array from top to bottom to pass through the window and move toward the silicon photonics wafer.

3. The silicon photonics wafer testing system according to claim 1, further comprising automatic test equipment integrated in the wafer prober and electrically connected to the integrated control module and the probe card, wherein the integrated control module drives the automatic test equipment to detect electrical characteristics or opto-electronic characteristics of the silicon photonics wafer.

4. The silicon photonics wafer testing system according to claim 1, further comprising a distance sensor disposed on the fiber holder and electrically connected to the integrated control module.

5. The silicon photonics wafer testing system according to claim 1, wherein the stage is a movable stage, and the upward-facing camera is assembled on a side of the stage to move with the stage.

6. The silicon photonics wafer testing system according to claim 1, wherein the positional information of the coupler is obtained by the integrated control module driving the downward-facing camera to be aligned with the coupler.

7. The silicon photonics wafer testing system according to claim 1, wherein the positional information of the coupler is obtained by the integrated control module from built-in information of the silicon photonics wafer.

8. A silicon photonics wafer testing method, adapted to the silicon photonics wafer testing system according to claim 1, the silicon photonics wafer testing method comprising:
transporting and loading the silicon photonics wafer onto the stage of the wafer prober;
performing an alignment step comprising:
alignment 1: aligning the upward-facing camera with a probe of the probe card;
alignment 2: aligning the upward-facing camera with the at least one optical fiber array; and
alignment 3: aligning the downward-facing camera with the silicon photonics wafer and the bonding pad thereon;
after the alignment step is completed, the integrated control module combines the positional information of the coupler of the silicon photonics wafer and drives the stage to move the silicon photonics wafer toward the probe card until the probe contacts the bonding pad of the silicon photonics wafer with preset probe pressing, and the integrated control module drives the optical coupling actuator to move the at least one optical fiber array to a position corresponding to the coupler and then performs optical coupling until a preset distance is reached.

9. The silicon photonics wafer testing method according to claim 8, further comprising
driving the optical measurement instrument to perform optical testing on the silicon photonics wafer after the optical coupling is completed.

10. The silicon photonics wafer testing method according to claim 8, wherein the silicon photonics wafer testing system further comprises an automatic test equipment integrated in the wafer prober and electrically connected to the integrated control module and the probe card, and the silicon photonics wafer testing method further comprises:
driving, by the integrated control module, the optical measurement instrument and the automatic test equipment to perform opto-electronic testing on the silicon photonics wafer after the optical coupling is completed.

11. The silicon photonics wafer testing method according to claim 8, wherein the silicon photonics wafer testing system further comprises a distance sensor disposed on the fiber holder and electrically connected to the integrated control module, and the silicon photonics wafer testing method further comprises:
driving, by the integrated control module, the distance sensor to obtain a relative distance between the at least one optical fiber array and the silicon photonics wafer to obtain the preset distance.

12. The silicon photonics wafer testing method according to claim 8, wherein the alignment step further comprises alignment 4: aligning the downward-facing camera with the silicon photonics wafer and the coupler thereon to obtain the positional information of the coupler.

13. The silicon photonics wafer testing method according to claim 8, wherein the positional information of the coupler is obtained by the integrated control module from built-in information of the silicon photonics wafer.
